(19) United States
(12) Patent Application Publication
(10) Pub. No.: US 2025/0280497 A1
(43) Pub. Date: Sep. 4, 2025

(54) PRINTED CIRCUIT BOARD

(71) Applicant: SAMSUNG ELECTRO-MECHANICS CO., LTD., Suwon-si (KR)

(72) Inventors: Ho Seung JANG, Suwon-si (KR); Mi Geum KIM, Suwon-si (KR); Min Gyu PARK, Suwon-si (KR); Jong Eun PARK, Suwon-si (KR); Won Seok LEE, Suwon-si (KR); Sang Ik CHO, Suwon-si (KR); Sung HAN, Suwon-si (KR)

(73) Assignee: SAMSUNG ELECTRO-MECHANICS CO., LTD., Suwon-si (KR)

(21) Appl. No.: 19/027,142

(22) Filed: Jan. 17, 2025

(30) Foreign Application Priority Data
Feb. 29, 2024 (KR) 10-2024-0029618

(51) Int. Cl. H05K 1/11; H05K 1/02; H05K 1/03; H05K 3/40

(52) U.S. Cl. CPC H05K 1/115; H05K 1/0271; H05K 1/0306; H05K 3/4038; H05K 2201/09563; H05K 2201/09818; H05K 2201/10227

(57) ABSTRACT

The present disclosure relates to a printed circuit board including: a frame having a through-portion; a glass substrate in which at least a portion is disposed within the through-portion; a first insulating layer including a first insulating portion covering at least a portion of each of an upper surface of the frame and the glass substrate, a second insulating portion covering at least a portion of each of a lower surface of the frame and the glass substrate, and a third insulating portion filling at least a portion between the frame and the glass substrate; a through-via penetrating the glass substrate between its upper and lower surfaces; a first connection via penetrating at least a portion of the first insulating portion and directly connected to an upper surface of the through-via; and a second connection via penetrating at least a portion of the second insulating portion and directly connected to a lower surface of the through-via.

### CROSS-REFERENCE TO RELATED APPLICATION(S)

This application claims benefit of priority to Korean Patent Application No. 10-2024-0029618 filed on Feb. 29, 2024 in the Korean Intellectual Property Office, the disclosure of which is incorporated herein by reference in its entirety.

### TECHNICAL FIELD

The present disclosure relates to a printed circuit board.

Recently, large-area, highly stacked multilayer structures, and miniaturization have become essential for high performance of package substrates. Meanwhile, Copper Clad Laminates (CCLs) is generally used as a core substrate included in a package substrate, however, in the case of the CCLs, warpage is likely to occur due to a low modulus and high coefficient of thermal expansion, and there are limitations in implementing microcircuits. Accordingly, warpage may be suppressed by having a high modulus and a low coefficient of thermal expansion, and also, there is a need for core substrates including a new material, such as an inorganic material, which allow for easier microcircuit implementation due to their smooth surfaces. However, in the case of a core substrate including an inorganic material, when a through-via is formed, some defects may occur at an inlet portion of an upper end and a lower end, during processing of the through-hole,, which may be a starting point for cracks after commercialization.

### SUMMARY

An aspect of the present disclosure is to provide a printed circuit board which may prevent cracks from occurring due to thermal shock even when a through-via is formed in a core layer that includes an inorganic material, such as a glass substrate.

One of the various solutions provided by the present disclosure is to provide a printed circuit board with a structure that may offer advantages for thermal shock from a stress perspective, by forming one or more gap portions, a space separated between a through-via and a core layer, on a side surface of an upper portion and/or a side surface of a lower portion of the through-via, and filling the gap portions with insulating material.

For example, a printed circuit board according to an example embodiment including: a first insulating layer; a through-via penetrating through at least a portion of the area between an upper surface and a lower surface of the first insulating layer and having one or more gap portions separating at least a portion of one or more of a side surface of an upper portion and a side surface of a lower portion from the first insulating layer; and a second insulating layer disposed on the first insulating layer, covering at least a portion of one or more of a side surface of an upper portion and a side surface of a lower portion of the through-via, and filling at least portions of each of the one or more gap portions.

For example, a printed circuit board according to an example embodiment including: a glass substrate; a through-hole penetrating between an upper surface and a lower surface of the glass substrate; a metal via filling at least a portion of the through-hole; one or more gap portions respectively disposed between a side surface of an upper portion of the metal via and a wall surface of the through-hole, and between a side surface of a lower portion of the metal via and a wall surface of the through-hole; and an insulating layer disposed on the glass substrate and filling at least portions of each of the one or more gap portions.

One of the various effects of the present disclosure is to provide a printed circuit board that may prevent cracks from occurring due to thermal shock even when a through-via is formed in a core layer that includes an inorganic material, such as a glass substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is an enlarged cross-sectional view schematically illustrating region A of the printed circuit board shown in FIG. 3;

FIGS. 5A and 5B are plan views schematically illustrating various examples of the cut surface I-I′ of region A of the printed circuit board shown in FIG. 4, respectively;

FIGS. 6A to 6I are process-sectional views schematically illustrating an example of manufacturing the printed circuit board shown in FIG. 3;

FIG. 7 is a cross-sectional view schematically illustrating another example of a printed circuit board; and

FIG. 8 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clarity in the description.

### Electronic Device

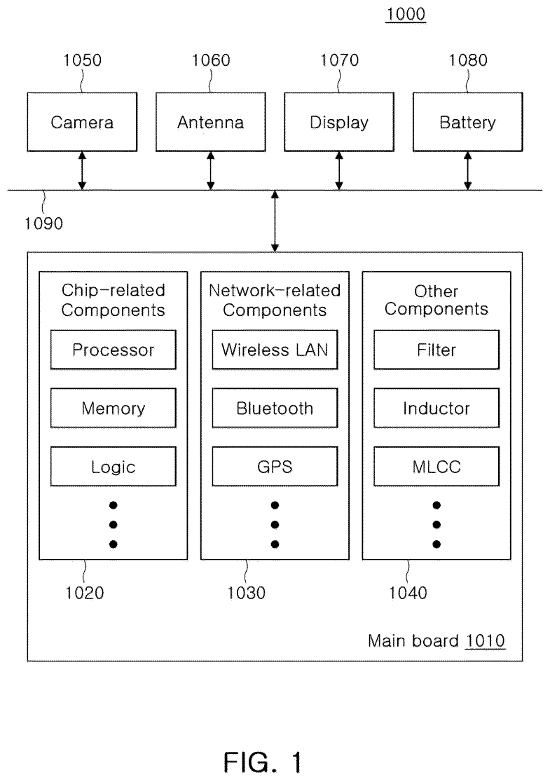

FIG. 1 is a block diagram schematically illustrating an example of an electronic device system.

Referring to FIG. 1, an electronic device 1000 includes a main board 1010 therein. Chip-related components 1020, network-related components 1030, and other components 1040, and the like, are physically and/or electrically connected to the main board 1010. These components are also coupled to other electronic components, described below, to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related components 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, these other components are not limited thereto, and may also include passive components in the form of chip components used for various other purposes. In addition, other components 1040 may be coupled to each other, together with the chip-related components 1020 and/or the network-related components 1030.

Depending on the type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition, other electronic components used for various purposes depending on the type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, or an automotive component. However, the electronic device 1000 is not limited thereto, and may be any other electronic device that processes data as well.

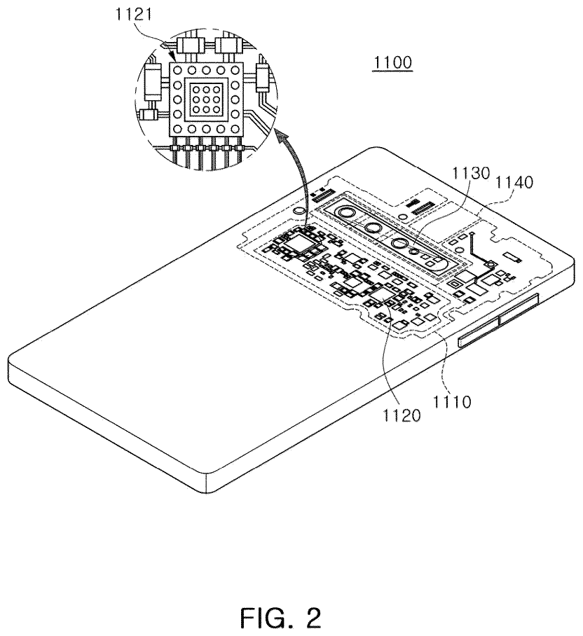

FIG. 2 is a perspective view schematically illustrating an example of an electronic device.

Referring to FIG. 2, an electronic device may be, for example, a smartphone 1100. A motherboard 1110 may be accommodated in the smartphone 1100, and various components 1120 may be physically and/or electrically connected to the motherboard 1110. Furthermore, other components that may or may not be physically and/or electrically connected to the motherboard 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may take the form of a printed circuit board in which an electronic component including an active component and/or a passive component is mounted on a surface. Alternatively, the component package 1121 may have the form of a printed circuit board in which an active component and/or a passive component is embedded. On the other hand, the electronic device is not necessarily limited to the smartphone 1100, and may be other electronic devices as described above.

### Printed Circuit Board

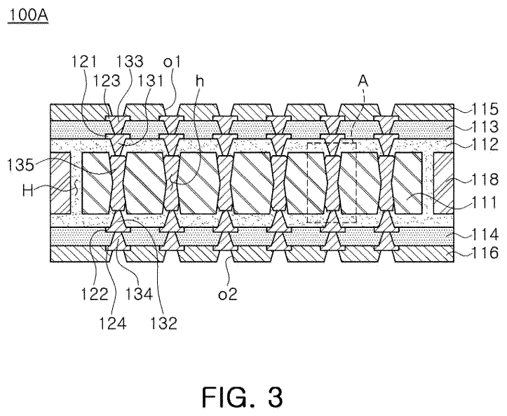

FIG. 3 is a cross-sectional view schematically illustrating an example of a printed circuit board.

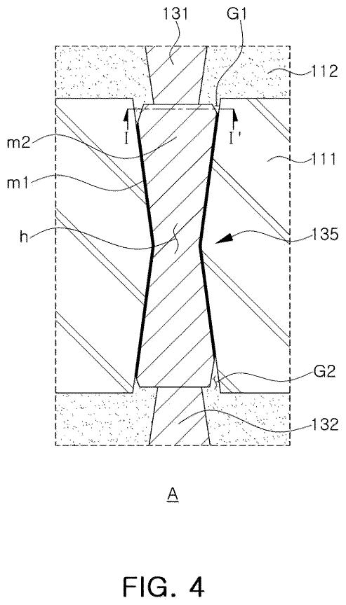

FIG. 4 is an enlarged cross-sectional view schematically illustrating region A of the printed circuit board shown in FIG. 3.

Referring to the drawings, a printed circuit board 100A according to an example embodiment may include: a first insulating layer 111, a through-via 135 penetrating through at least a portion of the area between an upper surface and a lower surface of the first insulating layer 111 and having one or more gap portions G1 and G2 separating at least a portion of a side surface of an upper portion and/or a side surface of a lower portion from the first insulating layer 111, and a second insulating layer 112 disposed on the first insulating layer 111 and covering at least a portion of an upper portion and/or a lower portion of the through-via 135 and filling at least portions of each of the one or more gap portions G1 and G2. For example, the second insulating layer 112 may be disposed on the upper surface and the lower surface of the first insulating layer 111 to cover at least portions of each of the upper portion and the lower portion of the through-via 135, and may fill at least portions of each of one or more first gap portions G1 formed on a side surface of an upper portion of the through-via 135 and one or more second gap portions G2 formed on a side surface of a lower portion of the through-via 135. The upper portion of the through-via 135 may include a portion of the through-via 135 extending downward from an upper surface of the through-via 135. The lower portion of the through-via 135 may include another portion of the through-via 135 extending upward from a lower surface of the through-via 135.

In this manner, in the printed circuit board 100A according to an example embodiment, one or more gap portions G1 and G2, which is a space between the first insulating layer 111 and the through-via 135, may be formed on the side surface of the upper portion and/or the side surface of the lower portion of the through-via 135 penetrating through the first insulating layer 111, and at least portions of each of the one or more gap portions G1 and G2 may be filled with the second insulating layer 112. Accordingly, even when the first insulating layer 111 includes an inorganic material such as a glass substrate as a core layer, the printed circuit board 100A may have a structure that is advantageous for thermal shock in terms of stress. Thus, the occurrence of cracks caused by thermal shock may be prevented.

For example, when a through-hole is formed in a glass substrate and is then filled with copper (Cu) fill plating to form a Through Glass Via (TGV), and an insulating layer is stacked thereon, and a reflow process is then performed from room temperature to approximately 260° C., if compressive stress applied to inlet portions of an upper portion and a lower portion of the TGV is compared, the compressive stress may be significantly lower in a case in which the gap portion is formed and is then filled with an insulating material than a case in which the gap portion is not formed. More specifically, in comparison with a TGV simply filled with copper (Cu) without the gap portion (Comparative Example 1), when a case in which the gap portion is formed on side surfaces of an upper portion and a lower portion of the TGV filled with copper (Cu) and is then filled with Ajinomoto Build-up Film (ABF) (Inventive Example 2), and a case in which the gap portion is formed on the side surfaces of the upper portion and the lower portion of the TGV filled with copper (Cu) and is then filled with Prepreg (PPG) (Inventive Example 3) are compared, the compressive stress may be improved to approximately 1:0.02:0.11 (Comparative Example 1: Inventive Example 2: Inventive Example 3), respectively. Accordingly, cracks due to stress applied by thermal shock may be suppressed through a structure in which the gap portion is formed and is then filled with the insulating material.

Meanwhile, the upper surface and/or the lower surface of the first insulating layer 111 may have a step portion relative to the upper surface and/or lower surface of the through-via 135, respectively. For example, the upper surface of the first insulating layer 111 may be disposed above the upper surface of the through-via 135, and the lower surface of the first insulating layer 111 may be disposed below the lower surface of the through-via 135. For example, the upper surface and the lower surface of the through-via 135 may be recessed inwardly from the through-via 135 relative to the upper surface and the lower surface of the first insulating layer 111, respectively. At least a portion of the recessed space may also be filled with the second insulating layer 112, and accordingly, the structure may be more advantageous for thermal shock. Additionally, the reliability of the through-via 135 may be further improved.

Meanwhile, the first insulating layer 111 may include an inorganic insulating material. In another example, the first insulating layer 111 may include a glass substrate. For example, the first insulating layer 111 may include plate glass. However, the present disclosure is not limited to this, and other materials may be used as long as they can form one or more of the above-described gap portions G1 and G2 in addition to the glass substrate. On the other hand, the second insulating layer 112 may include an organic insulating material, and since the organic insulating material fills one or more of the gap portions G1 and G2, the organic insulating material may be more advantageous from a stress perspective. The second insulating layer 112 may include Prepreg (PPG) or Ajinomoto Build-up Film (ABF), but the present disclosure is not limited thereto, and the second insulating layer 112 may include other organic insulating materials.

Meanwhile, the through-via 135 may be a metal via 135 configured to fill at least a portion of the through-hole h penetrating between the upper surface and the lower surface of the first insulating layer 111. One or more first gap portions G1 may be formed between a side surface of an upper portion of the metal via 135 and a wall surface of the through-hole h, and one or more second gap portions G2 may be formed between a side surface of a lower portion of the metal via 135 and the wall surface of the through-hole h. The metal via 135 may include a seed layer m1 disposed on a portion of the wall surface of the through-hole h and a metal layer m2 filling at least a portion of the through-hole h. At least a portion of the one or more first and second gap portions G1 and G2 may be disposed in another portion of the wall surface of the through-hole h, for example, between a portion of the wall surface of the through-hole h on which the seed layer m1 is not formed and a side surface of the metal layer m2. In some regions where the one or more first and second gap portions G1 and G2 are formed, a portion of the seed layer m1 may be separated from the wall surface of the through-hole h and may remain on the side surface of the metal layer m2. In this manner, the metal via 135 may be formed by forming a seed layer in the through-hole h and then performing fill plating thereon, and then, when portions of the seed layer and the fill plating layer are removed in the subsequent polishing process, one or more first and second gap portions G1 and G2 may be formed. In this case, the recessed space described above, such as dishing or a dimple, may also be formed. Based on this structure, a structure advantageous in terms of thermal stress may be implemented.

Meanwhile, in cross-section, in the through-via 135, a maximum width in each of the upper portion and the lower portion thereof may be wider than a minimum width in a center portion between the upper portion and the lower portion thereof. For example, the through-hole h at least partially filled with the through-via 135 may have an approximately hourglass shape, and accordingly, the through-via 135 may have a structure approximately corresponding thereto. The structure may be more advantageous for stress distribution.

Meanwhile, the printed circuit board 100A according to an example embodiment may further include a frame 118 having a through-hole h. At least a portion of the first insulating layer 111 may be disposed in the through-hole h of the frame 118. The second insulating layer 112 may cover at least a portion of the frame 118 and may fill at least a portion of the through-hole h. The frame 118 may be used as a jig during a process, and thus may be more advantageous in process warpage control, or the like. Additionally, a plurality of through-portions H may be formed in a large-area frame 118, and by utilizing these, a plurality of printed circuit boards 100A may be manufactured through the same process, and may then be separated in a cutting process, thereby increasing productivity.

Meanwhile, the printed circuit board 100A according to an example embodiment may further include a first interconnection layer 121 disposed on the upper surface of the second insulating layer 112, a second interconnection layer 122 arranged on the lower surface of the second insulating layer 112, a first connection via 131 penetrating through at least a portion of the second insulating layer 112 and connecting at least a portion of the first interconnection layer 121 to the upper surface of the through-via 135, and a second connection via 132 penetrating through at least another portion of the second insulating layer 112 and connecting at least a portion of the second interconnection layer 122 to the lower surface of the through-via 135. The first and second connection vias 131 and 132 may be directly connected to the upper surface and lower surface of the through-via 135, respectively. The first and second connection vias 131 and 132 may be tapered in opposite directions in cross-section. Through this structure, the second insulating layer 112 may more easily cover the upper portion and/or the lower portion of the through-via 135, and may fill one or more gap portions G1 and G2. Accordingly, a structure advantageous for the stress structure may be more easily implemented.

Meanwhile, the printed circuit board 100A according to an example embodiment may include: a third insulating layer 113 disposed on the upper surface of the second insulating layer 112 and covering at least a portion of the first interconnection layer 121, a fourth insulating layer 114 disposed on the lower surface of the second insulating layer 112 and covering at least a portion of the second interconnection layer 122, a third interconnection layer 123 disposed on an upper surface of the third insulating layer 113, a fourth interconnection layer 124 disposed on a lower surface of the fourth insulating layer 114, a third connection via 133 penetrating through at least a portion of the third insulating layer 113 and connecting at least portions of each of the first and third interconnection layers 121 and 123 to each other, a fourth connection via 134 penetrating through at least a portion of the fourth insulating layer 114 and connecting at least portions of each of the second and fourth interconnection layers 122 and 124 to each other, a first resist layer 115 disposed on an upper surface of the insulating layer 113 and having a first opening o1 exposing at least a portion of the third interconnection layer 123, and a second resist layer 116 disposed on a lower surface of the fourth insulating layer 114 and having a second opening 02 exposing at least a portion of the fourth interconnection layer 124. The third and fourth connection vias 133 and 134 may be tapered in opposite directions in cross-section. For example, the printed circuit board 100A according to an example embodiment may have a multilayer printed circuit board structure, and accordingly, the printed circuit board 100A may be used as a Flip-Chip Board (FCB), a Ball Grid Array (BGA), an interposer board, a package board, or the like. However, the present disclosure is not limited thereto, and may be applied to various other types of boards.

Hereinafter, components of a printed circuit board 100A according to an example embodiment will be described in more detail with reference to the drawings.

The first insulating layer 111 may include a glass substrate. The glass substrate may include glass, which is an amorphous solid. The glass may include, for example, pure silicon dioxide (approximately 100% SiO₂), soda lime glass, borosilicate glass, and alumino-silicate glass. However, the present disclosure is not limited thereto, and alternative glass materials, for example, fluorine glass, phosphate glass, chalcogen glass, or the like, may also be used. Additionally, other additives may be further included to form glass with specific physical properties. These additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these elements and others. The glass substrate may be distinguished from organic insulating materials including glass fiber (e.g., Glass Fiber, Glass Cloth or Glass Fabric), for example, Copper Clad Laminate (CCL), Prepreg (PPG), or the like. For example, the glass substrate may include plate glass. However, the present disclosure is not limited thereto, and in addition to the glass substrate, other materials may be used as long as one or more of the gap portions G1 and G2 described above may be formed. For example, a silicon substrate, a ceramic substrate, or the like, may also be considered as a material for the first insulating layer 111.

Each of the second to fourth insulating layers 112, 113, and 114 and the first and second resist layers 115 and 116 may include an organic insulating material. The organic insulating material may include a thermosetting resin such as an epoxy resin, a thermoplastic resin such as a polyimide, or an inorganic filler, an organic filler, and/or glass fiber (e.g., Glass Fiber, Glass Cloth, or Glass Fabric) along with the resin. For example, the organic insulating material may be Prepreg (PPG), an Ajinomoto Build-up Film (ABF), Photoimageable Dielectric (PID), Solder Resist (SR), or the like, but the present disclosure is not limited thereto. If necessary, each of the second to fourth insulating layers 112, 113 and 114 and the first and second resist layers 115 and 116 may be formed of a plurality of layers. The first and second resist layers 115 and 116 may have the first and second openings o1 and o2, respectively, and each of the first and second openings o1 and o2 may be provided in plural. Pad patterns of each of the third and fourth interconnection layers 123 and 124 exposed through the first and second openings o1 and o2 may be in the form of Solder Mask Defined (SMD) and/or Non Solder Mask Defined (NSMD).

The frame 118 may include various materials. For example, the frame 118 may include an organic insulating material such as Copper Clad Laminate (CCL). Alternatively, the frame 118 may include an inorganic insulating material such as silicon or ceramic. Alternatively, the frame 118 may include a metal such as copper (Cu). The present disclosure is not limited thereto. The frame 118 may have a through-portion H. The through-portion H may penetrate between an upper surface and a lower surface of the frame 118. The through-portion H may have a shape corresponding to the first insulating layer 111. If necessary, the through-portion H may be formed in the form of a blind cavity. The through-portion H may continuously surround a side surface of the first insulating layer 111. For example, the through-portion H may have an approximately square shape in plan view. If necessary, the frame 118 may be formed of a plurality of units, and the number of the plurality of units may not be particularly limited.

Each of the first to fourth interconnection layers 121, 122, 123 and 124 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the first to fourth interconnection layers 121, 122, 123 and 124 may perform various functions according to the design. For example, the first to fourth interconnection layers 121, 122, 123 and 124 may include a signal pattern, a power pattern, and a ground pattern. Such patterns may each have various shapes such as a line, a plane, and a pad. Each of the first to fourth interconnection layers 121, 122, 123 and 124 may include a seed layer and a plating layer. The seed layer may be formed by electroless plating (or chemical copper), and may be formed by a sputtering process if necessary. Alternatively, the first to fourth interconnection layers 121, 122, 123 and 124 may be formed using both the electroless plating and the sputtering process. The plating layer may be formed by electrolytic plating (or electrolytic copper). When each of the second to fourth insulating layers 112, 113 and 114 is formed of a plurality of layers, the first to fourth wiring layers 121, 122, 123 and 124 may be formed of a plurality of layers by correspondingly. The first to fourth interconnection layers 121, 122, 123 and 124 may be respectively protruded on the second to fourth insulating layers 122, 123 and 124, but may also be respectively embedded in the second to fourth insulating layers 112, 113 and 114.

Each of the first to fourth connecting vias 131, 132, 133 and 134 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the first to fourth connecting vias 131, 132, 133 and 134 may perform various functions according to the design. For example, the first to fourth connecting vias 131, 132, 133 and 134 may include a signal via, a power via, and a ground via. Each of the first to fourth connecting vias 131, 132, 133 and 134 may include a filled via in which a via hole is filled with the metal, but may also include a conformal via in which the metal is disposed along a wall surface of the via hole. Each of the first to fourth connecting vias 131, 132, 133 and 134 may have a tapered shape in cross-section. For example, the first and third connecting vias 131 and 133 may be configured so that a width of an upper end thereof is wider than a width of a lower end thereof in cross-section, and the second and fourth connecting vias 132 and 134 may be configured so that a width of an upper end thereof is wider than a width of a lower end in cross-section. Each of the first to fourth connecting vias 131, 132, 133 and 134 may include the same seed layer and plating layer included in the first to fourth interconnection layers 121, 122, 123 and 124. The first to fourth connecting vias 131, 132, 133 and 134 may each be provided in plural.

The through-via 135 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. The through-via 135 may include a metal via 135 filling at least a portion of the through-hole h. The metal via 135 may perform various functions depending on the design. For example, the through-via 135 may include a signal via, a power via, and a ground via. One or more first gap portions G1 may be formed between the side surface of the upper portion of the metal via 135 and the wall surface of the through-hole h, and one or more second gap portions G2 may be formed between the side surface of the lower portion of the metal via 135 and the wall surface of the through-hole h. The metal via 135 may include a seed layer m1 disposed on a portion of the wall surface of the through-hole h and a metal layer m2 filling at least a portion of the through-hole h. One or more first and second gap portions G1 and G2 may be disposed between another portion of the through-hole h, for example, a portion in which the seed layer m1 is not formed, and a side surface of the metal layer m2. For example, the metal via 135 may be formed by forming a seed layer in the through-hole h and then performing fill plating, and when a portion of the seed layer and a portion of a fill plating layer are removed in a subsequent polishing process, one or more first and second gap portions G1 and G2 may be formed. Additionally, the above-described recessed space, for example, dishing or a dimple, may be formed. The metal via 135 may be provided in plural.

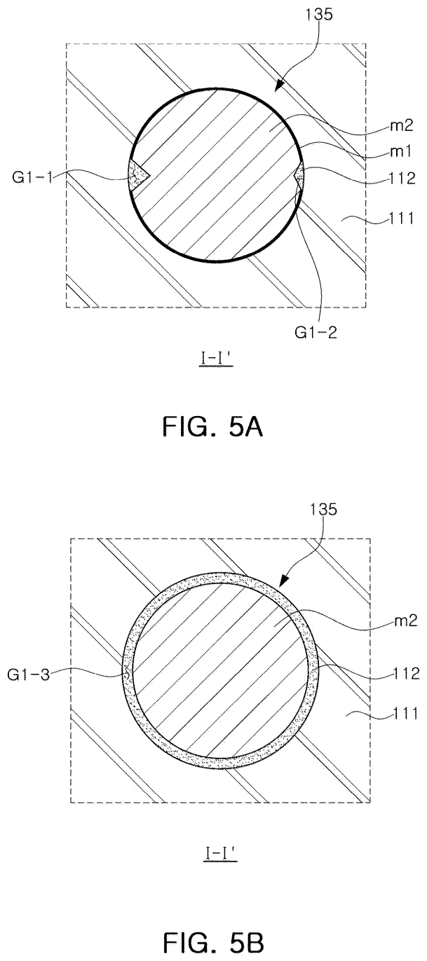

FIGS. 5A and 5B are plan views schematically illustrating various examples of cut surface I-I′ of region A of the printed circuit board shown in FIG. 4, respectively.

Referring to FIG. 5A, one or more first gap portions G1 may be provided in plural. For example, the one or more first gap portions G1 may include a first-first gap portion G1-1 and a first-second gap portion G1-2, which may be spaced apart from each other. The first-first and first-second gap portions G1-1 and G1-2 may have different sizes, for example, different widths, depths, and the like. The first gap portion G1 may include a greater number of gap portions than those illustrated in the drawing. The above-described content may be substantially equally applied to the second gap portion G2. In this manner, gap portions of various sizes may be formed in various positions and may be filled with insulating materials, thereby implementing a structure advantageous for thermal shock while increasing the degree of design freedom.

Referring to FIG. 5B, one or more first gap portions G1 may be a single continuous component. For example, one or more first gap portions G1 may include one first-third gap portion G1-3 continuously surrounding a side surface of the upper portion of the through-via 135. The above-described contents may be substantially equally applied to the second gap portion G2. In this manner, the gap portions may be formed more widely and continuously, thus implementing a structure advantageous for thermal shock may be implemented.

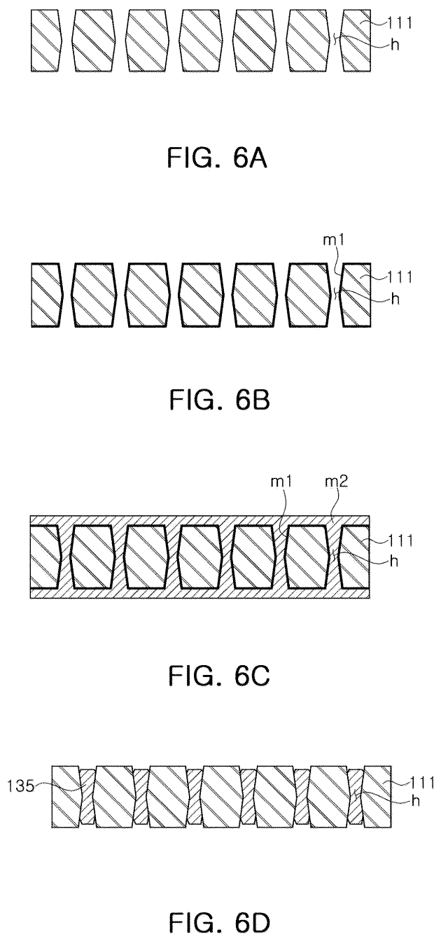

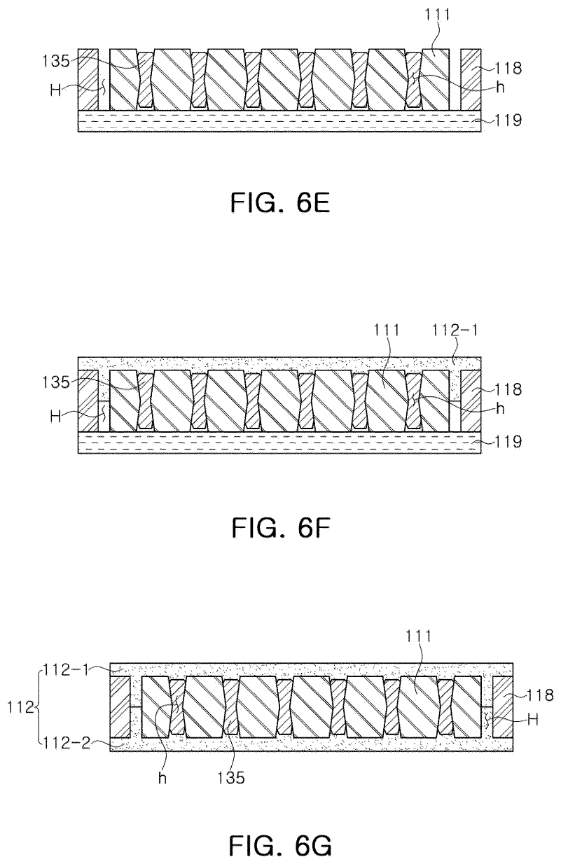

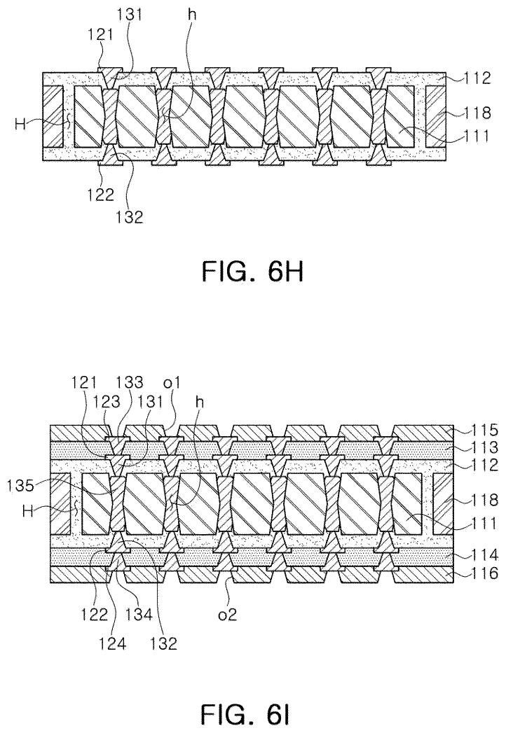

FIGS. 6A to 6I are process cross-sectional views schematically illustrating an example of manufacturing the printed circuit board shown in FIG. 3.

Referring to FIG. 6A, a first insulating layer 111 may be prepared. The first insulating layer 111 may be a glass substrate such as plate glass as described above, but the present disclosure is not limited thereto. Next, a through-hole h penetrating through the first insulating layer 111 may be formed. The through-hole h may be formed in using a chemical method or a mechanical method, depending on the material of the first insulating layer 111. For example, etching, blasting, laser, plasma, or the like, may be used as a method of forming the through-hole h.

Referring to FIG. 6B, a seed layer m1 covering the through-hole h and the first insulating layer 111 may be formed on a wall surface of the through-hole h and an upper surface and a lower surface of the first insulating layer 111. The seed layer m1 may be formed by electroless plating (or chemical copper plating), but the present disclosure is not limited thereto. If necessary, the seed layer m1 may be formed in multiple layers.

Referring to FIG. 6C, a metal layer m2 may be formed on the seed layer m1. The metal layer m2 may be formed by fill plating. The fill plating may use electrolytic plating (or electroplating), but the present disclosure is not limited thereto. The metal layer m2 may fill the through-hole h and may also be formed on the upper surface and lower surface of the first insulating layer 111.

Referring to FIG. 6D, at least portions of the seed layer m1 and the metal layer m2 disposed on the upper surface and lower surface of the first insulating layer 111 may be removed. Additionally, a through-via 135 and one or more first and second gap portions G1 and G2 may be formed. For example, a seed layer m1 and a metal layer m2 formed on the surface of the first insulating layer 111 may be removed in a polishing process such as Chemical Mechanical Planarization (CMP), thus forming a through-via 135. In this case, the through-via 135 may be removed relatively more than the first insulating layer 111 in an inlet portion of an upper portion and/or a lower portion of the through-via 135, thus forming one or more first and/or second gap portions G1 and G2. Additionally, an upper surface and/or a lower surface of the through-via 135 may be recessed inwardly as a whole, thus forming dishing or dimples.

Referring to FIG. 6E, a frame 118 with a through-portion H may be prepared. Additionally, the first insulating layer 111 with the through-via 135 formed in the through-portion H of the frame 118 may be disposed using a tape 119. The frame 118 may be used as a jig. The through-portion H may be provided in plural, and the first insulating layer 111 having the through-vias 135 formed in each of the through-portions H may be disposed.

Referring to FIG. 6F, a second-first insulating layer 112-1 may be laminated on the frame 118 and an upper side of the first insulating layer 111. In this case, one or more first gap portions G1 may be filled with the second-first insulating layer 112-1.

Referring to FIG. 6G, the tape 119 may be removed. Additionally, a second-second insulating layer 112-2 may be laminated on the frame 118 and a lower side of the first insulating layer 111. In this case, one or more second gap portions G2 may be filled with the second-second insulating layer 112-2. Meanwhile, after a curing process, the second-first and second insulating layers 112-1 and 112-2 may be integrated to form a second insulating layer 112.

Referring to FIG. 6H, first and second interconnection layers 121 and 122 and first and second connection vias 131 and 132 may be formed on the second insulating layer 112. For example, after processing a via hole with a laser drill or the like in a required position of the second insulating layer 112, a circuit process such as Tenting (TT), Additive Process (AP), Semi Additive Process (SAP), or Modified Semi Additive Process (MSAP), or the like, may be performed, thus forming first and second interconnection layers 121 and 122 and first and second connection vias 131 and 132.

Referring to FIG. 6I, a build-up process may be additionally performed. For example, the third and fourth insulating layers 113 and 114 may be laminated on the upper side and the lower side of the second insulating layer 112, respectively. Additionally, using the via hole formation process and the circuit process described above, third and fourth interconnection layers 123 and 124 and third and fourth connection vias 133 and 134 may be formed on the third and fourth insulating layers 113 and 114, respectively. Next, the first and second resist layers 115 and 116 may be formed on the third and fourth insulating layers 113 and 114, and the first and second openings o1 and o2 may be formed using a photolithography process or laser processing. Through a series of processes, a printed circuit board 100A according to an example embodiment may be manufactured.

Other descriptions may be substantially the same as those described in the printed circuit board 100A according to an example embodiment described above, and therefore, duplicate descriptions will be omitted.

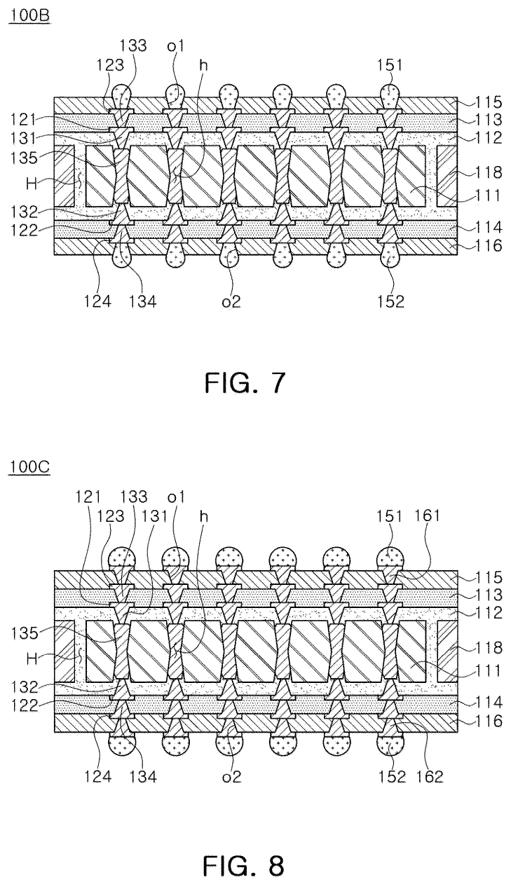

FIG. 7 is a cross-sectional view schematically illustrating another example of a printed circuit board.

Referring to FIG. 7, a printed circuit board 100B according to another example embodiment may further include a first electrical connection metal 151 disposed on a first opening o1 of a first resist layer 115 and connected to at least an exposed portion of a third interconnection layer 123, and a second electrical connection metal 152 disposed on a second opening o2 of a second resist layer 116 and connected to at least an exposed portion of a fourth interconnection layer 124, in the printed circuit board 100A according to an example embodiment described above, the first and second electrical connection metals 151 and 152 may connect the printed circuit board 100B to another substrate or electronic components, or the like. The first and second electrical connection metals 151 and 152 may be formed of a conductive material, such as solder, or the like, but this is only an example and the material is not particularly limited thereto. Each of the first and second electrical connection metals 151 and 152 may be a land, a ball, a pin, or the like. Each of the first and second electrical connection metals 151 and 152 may be formed of a multilayer or a single layer. In the case where the first and second electrical connection metals 151 and 152 are formed of a multilayer, the first and second electrical connection metals 151 and 152 may include a copper pillar and a solder formed on the copper pillar, and in a case in which the first and second electrical connection metals 151 and 152 are formed of a single layer, the first and second electrical connection metals 151 and 152 may include tin-silver solder or copper, but the present disclosure is not limited thereto. Each of the first and second electrical connection metals 151 and 152 may be formed in plural.

Other descriptions may be substantially the same as those described in the printed circuit board 100A according to an example embodiment described above, and therefore, duplicate descriptions thereof will be omitted.

FIG. 8 is a cross-sectional view schematically illustrating another example of a printed circuit board.

Referring to FIG. 8, a printed circuit board 100C according to another example embodiment may further include a first underbump metal 161 disposed between at least an exposed portion of a third interconnection layer 123 and a first electrical connection metal 151, and a second underbump metal 162 disposed between at least an exposed portion of a fourth interconnection layer 124 and a second electrical connection metal 152, in the printed circuit board 100B according to another example embodiment described above.

The first and second underbump metals 161 and 162 may improve connection reliability of the first and second electrical connection metals 151 and 152. Each of the first and second underbump metals 161 and 162 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure not limited thereto. Each of the first and second underbump metals 161 and 162 may include a seed layer and a plating layer. The seed layer may be formed by electroless plating (or chemical copper), and, if necessary, may be formed by a sputtering process. Alternatively, the seed layer may be formed using both the electroless plating and the sputtering process. The plating layer may be formed by electrolytic plating (or electrolytic copper). Each of the first and second underbump metals 161 and 162 may be formed of a via portion and a pad portion, but the present disclosure is not limited thereto, and each of the first and second underbump metals 161 and 162 may be formed only of the via portion. For example, each of the first and second underbump metals 161 and 162 may have a structure in which vias protrude onto the first and second resist layers 115 and 116 without pads. Each of the first and second underbump metals 161 and 162 may be provided in plural.

Other descriptions may be substantially the same as those described in the printed circuit board 100A according to an example embodiment and the printed circuit board 100B according to another example embodiment described above, and therefore, duplicate descriptions will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, exposing may include partial exposing as well as a case of complete exposing, and exposure may refer to exposing a corresponding component from embedding. For example, exposing a pad by an opening may be exposing the pad from a resist layer, and a surface treatment layer or the like may be further disposed on the exposed pad.

In the present disclosure, being disposed in a through-portion or a through-hole may include not only cases in which an object is disposed completely in the through-portion or the through-hole, but also cases in which the object partially protrudes therefrom upwardly or downwardly in cross-section. For example, when the object is disposed in the through-portion or the through-hole in plan view, this may be determined in a broader sense.

In the present disclosure, determination may be performed by accounting for process errors, positional deviations, errors at the time of measurement, which may occur during the manufacturing process. For example, being substantially vertical may include not only being completely vertical but also being approximately vertical. Furthermore, being substantially coplanar may include not only a case in which elements are completely on the same plane, but also a case in which the elements are approximately on the same plane.

In the present disclosure, the same insulating material may denote not only the same insulating material but also the same type of insulating material. Accordingly, the compositions of the insulating materials may be substantially the same, but specific composition ratios thereof may vary slightly.

In the present disclosure, the term “on the cross-section” may refer to a cross-sectional shape when an object is cut vertically, or a cross-sectional shape when the object is viewed in a side-view. Furthermore, the term “on a plane” may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected includes not only directly connected but also indirectly connected through an adhesive layer or the like. Furthermore, a meaning of electrically connected includes both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

1-26. (canceled)

27. A printed circuit board, comprising:
a frame having a through-portion;
a glass substrate in which at least a portion thereof is disposed within the through-portion;
a first insulating layer including a first insulating portion covering at least a portion of each of an upper surface of the frame and an upper surface of the glass substrate, a second insulating portion covering at least a portion of each of a lower surface of the frame and a lower surface of the glass substrate, and a third insulating portion filling at least a portion between the frame and the glass substrate within the through-portion;
a through-via penetrating through at least a portion of the glass substrate, between an upper surface and a lower surface of the glass substrate;
a first connection via penetrating through at least a portion of the first insulation portion and directly connected to an upper surface of the through-via; and
a second connection via penetrating through at least a portion of the second insulation portion and directly connected to a lower surface of the through-via.

28. The printed circuit board according to claim 27, wherein the first to third insulating portions are integrally formed without boundaries between each other.

29. The printed circuit board according to claim 28, wherein the first insulating layer includes Prepreg or Ajinomoto Build-up Film.

30. The printed circuit board according to claim 27, wherein the third insulating portion has a boundary surface between the upper surface and the lower surface of the frame.

31. The printed circuit board according to claim 27, wherein a thickness between the upper surface and the lower surface of the glass substrate is thicker than a thickness between an upper surface and a lower surface of the through-via.

32. The printed circuit board according to claim 31, wherein the upper surface of the glass substrate is disposed above the upper surface of the through-via, and
the lower surface of the glass substrate is disposed below the lower surface of the through-via.

33. The printed circuit board according to claim 31, further comprising:
one or more gap portions separating at least portions of one or more of a side surface of an upper end portion and a side surface of a lower end portion of the through-via from the glass substrate, respectively, and
the first insulating layer fills at least a portion of each of the one or more gap portions.

34. The printed circuit board according to claim 27, further comprising:
a through-hole penetrating through the glass substrate, between the upper surface and the lower surface of the glass substrate,
wherein the through-via includes a seed layer disposed on a wall surface of the through-hole and a metal layer disposed on the seed layer and filling at least a portion of the through-hole.

35. The printed circuit board according to claim 27, wherein the through-via has a substantially hourglass shape in a cross-section,
the first connection via has a substantially tapered side surface in which a width of an upper end portion is wider than a width of a lower end portion in the cross-section, and
the second connection via has a substantially tapered side surface in which a width of a lower end portion is wider than a width of an upper end portion in the cross-section.

36. The printed circuit board according to claim 27, further comprising:
a first wiring layer disposed on an upper surface of the first insulating portion and directly connected to the first connection via; and
a second wiring layer disposed on a lower surface of the second insulating portion and directly connected to the second connection via.

37. The printed circuit board according to claim 36, wherein no wiring layer is in direct contact with either the upper surface or the lower surface of the glass substrate.

38. The printed circuit board according to claim 36, further comprising:
a second insulating layer disposed on the upper surface of the first insulating portion and covering at least a portion of the first wiring layer;
a third insulating layer disposed on the lower surface of the second insulating portion and covering at least a portion of the second wiring layer;
a third wiring layer disposed on an upper surface of the second insulating layer;
a fourth wiring layer disposed on a lower surface of the third insulating layer;
a third connection via penetrating through at least a portion of the second insulating layer and connecting at least portions of each of the first and third wiring layers to each other; and
a fourth connection via penetrating through at least a portion of the third insulating layer and connecting at least portions of each of the second and fourth wiring layers to each other,
wherein the third connection via has a substantially tapered side surface in which a width of an upper end is wider than a width of a lower end in a cross-section, and
the fourth connection via has a substantially tapered side surface in which a width of a lower end is wider than a width of an upper end in the cross-section.

39. The printed circuit board according to claim 38, further comprising:
a first solder resist layer disposed on the upper surface of the second insulating layer and having a first opening exposing at least a portion of the third wiring layer; and
a second solder resist layer disposed on the lower surface of the third insulating layer and having a second opening exposing at least a portion of the fourth wiring layer.

40. The printed circuit board according to claim 27, wherein the frame is embedded in an outer side of the first insulating layer, and
an outer surface of the frame is exposed from an outer surface of the first insulating layer.

41. The printed circuit board according to claim 40, wherein the exposed outer surface of the frame and the outer surface of the first insulating layer are substantially coplanar with each other.

42. A method of manufacturing a printed circuit board, comprising:
forming a through-via penetrating through at least a portion a glass substrate, between an upper surface and a lower surface the glass substrate;
disposing at least a portion of the glass substrate within a through-portion of a frame;
forming a first insulating layer including a first insulating portion covering at least a portion of each of an upper surface of the frame and an upper surface of the glass substrate, a second insulating portion covering at least a portion of each of a lower surface of the frame and a lower surface of the glass substrate, and a third insulating portion filling at least a portion between the frame and the glass substrate within the through-portion;
forming a first connection via penetrating through at least a portion of the first insulation portion and directly connected to an upper surface of the through-hole via; and
forming a second connection via penetrating through at least a portion of the second insulation portion and directly connected to a lower surface of the through-hole via.

43. The method of manufacturing a printed circuit board according to claim 42, wherein the forming a through-via includes:
forming a through-hole penetrating through the glass substrate, between the upper surface and the lower surface of the glass substrate,
forming a seed layer on a wall surface of the through-hole and on the upper surface and the lower surface of the glass substrate,
forming a metal layer on the seed layer and filling at least a portion of the through-hole with the metal layer,
removing at least a portion of each of the seed layer and the metal layer disposed on the upper surface and the lower surface of the glass substrate, respectively,
wherein the seed layer includes a plurality of layers.

44. The method of manufacturing a printed circuit board according to claim 43, wherein in the removing at least a portion of each of the seed layer and the metal layer,
an upper surface of the metal layer is formed below the upper surface of the glass substrate, and
a lower surface of the metal layer is formed above the lower surface of the glass substrate.

45. The method of manufacturing a printed circuit board according to claim 43, wherein in the removing at least a portion of each of the seed layer and the metal layer,
one or more gap portions separating at least portions of one or more of a side surface of an upper end portion and a side surface of a lower end portion of the metal layer from the glass substrate, respectively, is formed within the through-hole, and
in the forming a first insulating layer,
the first insulating layer fills at least a portion of each of the one or more gap portions.

46. The method of manufacturing a printed circuit board according to claim 42, wherein in the disposing at least a portion of the glass substrate within the through-portion includes:
attaching a tape to a lower side of the frame, and
attaching the glass substrate to an upper surface of the tape exposed through the through-portion.

47. The method of manufacturing a printed circuit board according to claim 46, wherein the forming a first insulating layer includes:
laminating a first-first insulating layer above the frame and the glass substrate;
removing the tape; and
laminating a first-second insulating layer below the frame and the glass substrate.

48. The method of manufacturing a printed circuit board according to claim 47, wherein in the forming a first insulating layer,
the first-first and first-second insulating layers are integrated with each other to form the first insulating layer including the first to third insulating portions.

49. The method of manufacturing a printed circuit board according to claim 47, wherein in the forming a first insulating layer,
a boundary surface between the first-first and first-second insulating layers is formed in a level between the upper surface and the lower surface of the frame.

50. The method of manufacturing a printed circuit board according to claim 42, further comprising:
forming a first wiring layer directly connected to the first connection via on an upper surface of the first insulating portion; and
forming a second wiring layer directly connected to the second connection via on a lower surface of the second insulating portion.

51. The method of manufacturing a printed circuit board according to claim 50, wherein no wiring layer is formed in direct contact with either the upper surface or the lower surface of the glass substrate.

52. The method of manufacturing a printed circuit board according to claim 50, further comprising:
forming a second insulating layer covering at least a portion of the first wiring layer on the upper surface of the first insulating portion;
forming a third insulating layer covering at least a portion of the second wiring layer on the lower surface of the second insulating portion;
forming a third connection via penetrating through at least a portion of the second insulating layer and connected to the first wiring layer;
forming a fourth connection via penetrating through at least a portion of the third insulating layer and connected to the second wiring layer;
forming a third wiring layer connected to the third connection via on an upper surface of the second insulating layer; and
forming a fourth wiring layer connected to the fourth connection via on a lower surface of the third insulating layer.

53. The method of manufacturing a printed circuit board according to claim 52, further comprising:
forming a first solder resist layer having a first opening exposing at least a portion of the third wiring layer on the upper surface of the second insulating layer; and
forming a second solder resist layer having a second opening exposing at least a portion of the fourth wiring layer on the lower surface of the third insulating layer.

54. The method of manufacturing a printed circuit board according to claim 42, wherein the frame is embedded in an outer side of the first insulating layer, and
an outer surface of the frame is exposed from an outer surface of the first insulating layer.

55. The method of manufacturing a printed circuit board according to claim 54, wherein the exposed outer surface of the frame and the outer surface of the first insulating layer are substantially coplanar with each other.
